(19) United States
(12) Patent Application Publication
(10) Pub. No.: US 2006/0098731 A1
(43) Pub. Date: May 11, 2006

(54) Digital video data transmission system and method

(75) Inventor: Cheon-ho Bae, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/265,922

(22) Filed: Nov. 3, 2005

(30) Foreign Application Priority Data
Nov. 5, 2004 (KR) 10-2004-0089694

(51) Int. Cl. H03M 7/00; H04B 1/66

(52) U.S. Cl. 375/240.1; 341/50

(57) ABSTRACT

Provided are a digital video data transmission system and digital video data transmission method. The digital video data transmission system includes a transmitting unit transmitting valid first data in input digital video data having spatial locality to a bus as output encoding information without bit-inversion coding the first data, bit-inversion coding previous data of output encoding data corresponding to the input digital video data based on differential values of adjacent digital video data, and transmitting the bit-inversion coded value to the bus as the output encoding information; and a receiving unit not decoding output encoding information transmitted in parallel through the bus, i.e., the first data, but decoding output encoding information transmitted in parallel through the bus based on the differential values. The output encoding information includes the output encoding data and coding enable information that indicates whether to bit-inversion encode previous data of the output encoding data. The digital video data transmission system and digital video data transmission method can reduce the number of transitions of bits included in the digital video data transmitted through the bus, thereby reducing power consumption and electromagnetic interference.

### BACKGROUND OF THE INVENTION

This application claims the priority of Korean Patent Application No. 10-2004-89694, filed on Nov. 5, 2004, in the Korean Intellectual Property Office, the contents of which are incorporated herein in their entirety by reference.

1. Field of the Invention

The present invention relates to a digital video data transmission system, and more particularly, to a digital video data transmission system and digital video data transmission method using spatial locality of video data.

2. Description of the Related Art

A conventional digital video data transmission system comprises an image processing unit such as a video controller, a transmitting unit, a receiving unit, a bus that connects the transmitting unit and the receiving unit, and a display device such as a liquid crystal display (LCD) panel. A conventional digital video data transmission system is disclosed in U.S. Patent Laid-Open Publication No. 2003-0043141.

The image processing unit processes image data, i.e., digital video data, and transmits in parallel the processed digital video data to a register included in the transmitting unit. The register of the transmitting unit stores the processed digital video data and transmits the stored digital video data to a register of the receiving unit through the bus. A register of the receiving unit stores the received digital video data and transmits the stored digital video data to the display device.

Since the image processing unit performs a lot of operations, an interface device comprising the transmitting unit, the bus, and the receiving unit transmits a large amount of digital video data through the bus. The interface device consumes a lot of power. A variety of coding schemes have been proposed in order to reduce power consumption of the interface device. For example, a coding scheme entitled “Bus-Invert Coding for Lower Power I/O” appears in IEEE Transaction on VLSI Systems, Vol. 3, No. 1, 1995. However, a characteristic of digital video data such as spatial locality was not suggested in the coding scheme.

Since a lot of digital video data are transmitted through the bus, many transitions of bits included in digital video data occur in the bus, and a bit transition speed also increases. Therefore, electromagnetic wave interference between digital video data lines which constitute the bus increases.

### SUMMARY OF THE INVENTION

The present invention provides a digital video data transmission system and digital video data transmission method using the characteristic of digital video data.

According to an aspect of the present invention, there is provided a digital video data transmission system. The system includes a transmitting unit that: (i) transmits valid first data in input digital video data having spatial locality to a bus as output encoding information without bit-inversion coding the first data, (ii) bit-inversion codes previous data of output encoding data corresponding to the input digital video data based on differential values of adjacent digital video data, and (iii) transmits the bit-inversion coded value to the bus as the output encoding information. A receiving unit decoding output encoding information transmitted in parallel through the bus based on the differential values, but not decoding output encoding information transmitted in parallel through the bus, i.e., the first data, wherein the output encoding information includes the output encoding data and coding enable information that indicates whether to bit-inversion encode previous data of the output encoding data.

The output encoding information may comprise polarity change information indicating to invert the most significant bit included in previous data of the output encoding data when the polarity of the differential values changes; and bit-inversion coding information including information bit-inversion coded according to absolute values of the differential values.

The default polarity of the differential values may be established as positive (+).

The transmitting unit may transmit input digital video data to the bus as output encoding information without bit-inversion coding previous data of the output encoding data corresponding to the input digital video data when an absolute value of a differential value regarding the input digital video data exceeds a predetermined reference value; and the receiving unit does not decode the output encoding data that is not bit-inversion coded and is transmitted through the bus.

The transmitting unit may comprise a bit-inversion position deciding unit calculating a differential value between the input digital video data and previous data of the input digital video data, and outputting bit-inversion position information that indicates a bit-inversion position of previous data of output encoding data according to the absolute value of the differential value, the coding enable information, and the polarity change information; a bit-inversion coding unit bit-inversion coding previous data of the output encoding data corresponding to the input digital video data based on the polarity change information and the bit-inversion position information, and outputting the coded value as encoding data; and a transmitting multiplexer selecting one of the input digital video data and the encoding data in response to the coding enable information, and outputting the selected data as the output encoding data.

The bit-inversion position information may be output from a table including bit-inversion position codes according to absolute values of the differential values.

The Hamming distance of bit-inversion position codes included in the table is below 3, when the reference value is established as 63.

In one embodiment, the transmitting unit further comprises an input register storing previous data of the input digital video data.

In one embodiment, the transmitting unit further comprises a transmitting register storing the output encoding data.

The receiving unit may comprise a differential generating unit detecting the bit-inversion position by performing an exclusive OR (XOR) operation on the output encoding data and previous data of the output encoding data, generating an absolute value of the differential value corresponding to the detected bit-inversion position with reference to the table, and deciding the polarity of the differential value based on a change in the most significant bit of the output encoding data in comparison with the most significant bit included in previous data of the output encoding data; an adding unit outputting decoding data by adding the differential value to previous data of the output decoding data corresponding to the output encoding data; and a receiving multiplexer selecting one of the decoding data and the output encoding data in response to the coding enable information, and outputting the selected data as the output decoding data.

In one embodiment, the receiving unit further comprises a receiving register storing previous data of the output encoding data.

In one embodiment, the receiving unit further comprises an output register storing the output decoding data.

According to another aspect of the present invention, there is provided a digital video data transmission method, comprising: transmitting valid first data in input digital video data having spatial locality to a bus as output encoding information without bit-inversion coding the first data, bit-inversion coding previous data of output encoding data corresponding to the input digital video data based on differential values of adjacent digital video data, and transmitting the bit-inversion coded value to the bus as the output encoding information; transferring in parallel the output encoding information transmitted through the bus; and receiving the output encoding information transmitted through the bus, i.e., the first data, by not decoding the first data, and receiving the output encoding information transmitted through the bus by decoding the output encoding information based on the differential values, wherein the output encoding information includes the output encoding data and coding enable information that indicates whether to bit-inversion encode previous data of the output encoding data.

In one embodiment, the output encoding information comprises: polarity change information indicating to invert the most significant bit included in previous data of the output encoding data when the polarity of the differential values changes; and bit-inversion coding information including information bit-inversion coded according to absolute values of the differential values.

In one embodiment, a default polarity of polarity of the differential values is established as positive (+).

In one embodiment, the transmitting further comprises: transmitting input digital video data to the bus as output encoding information without bit-inversion coding previous data of the output encoding data corresponding to the input digital video data when an absolute value of a differential value regarding the input digital video data exceeds a predetermined reference value; and receiving the output encoding data that is not bit-inversion coded and is transmitted through the bus by not decoding the output encoding data.

In one embodiment, the transmitting comprises: calculating a differential value between the input digital video data and previous data of the input digital video data, and outputting bit-inversion position information that indicates a bit-inversion position of previous data of output encoding data according to the absolute value of the differential value, the coding enable information, and the polarity change information; bit-inversion coding previous data of the output encoding data corresponding to the input digital video data based on the polarity change information and the bit-inversion position information, and outputting the coded value as encoding data; and selecting one of the input digital video data and the encoding data in response to the coding enable information, and outputting the selected data as the output encoding data.

In one embodiment, the bit-inversion position information is output from a table including bit-inversion position codes according to absolute values of the differential values.

In one embodiment, the Hamming distance of bit-inversion position codes included in the table is below 3, when the reference value is established as 63.

In one embodiment, the transmitting further comprises storing previous data of the input digital video data.

In one embodiment, the transmitting further comprises storing the output encoding data.

In one embodiment, the receiving comprises: detecting the bit-inversion position by performing an exclusive OR (XOR) operation on the output encoding data and previous data of the output encoding data, generating an absolute value of the differential value corresponding to the detected bit-inversion position with reference to the table, and deciding the polarity of the differential value based on a change in the most significant bit of the output encoding data in comparison with the most significant bit included in previous data of the output encoding data; outputting decoding data by adding the differential value to previous data of the output decoding data corresponding to the output encoding data; and selecting one of the decoding data and the output encoding data in response to the coding enable information, and outputting the selected data as the output decoding data.

In one embodiment, the receiving further comprises storing previous data of the output encoding data.

In one embodiment, the receiving further comprises storing the output decoding data.

The digital video data transmission system and digital video data transmission method perform bit-inversion coding on digital video data having spatial data locality so as to shorten a Hamming distance according to differential values of data adjacent to digital video data, and transmit the bit-inversion coded digital video data to the bus. As a result, as the number of transition of bits included in the digital video data transmitted through the bus decreases, power consumption and electromagnetic interference decrease.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views the drawings are not necessarily to scale, emphasis instead being placed upon illustrating the principles of the invention.

FIG. 1 is a block diagram illustrating a digital video data transmission system according to an embodiment of the present invention.

FIG. 2 is a flow chart of a digital video data transmission method according to an embodiment of the present invention.

FIG. 3 is a block diagram of a transmitting unit of FIG. 1.

FIG. 4 is a flow chart describing the transmitting operation S110 of FIG. 2 that is applied to the transmitting unit of FIG. 3.

FIG. 5 is a table illustrating an exemplary transmitting operation of FIG. 4.

FIG. 6 is a table including exemplary bit-inversion position codes according to absolute values of differential values.

FIG. 7 is an example of output encoding information generated by the transmitting unit of FIG. 3 according to the transmitting operation of FIG. 4.

FIG. 8 is a block diagram of a receiving unit of FIG. 1.

FIG. 9 is a flow chart illustrating the receiving operation S130 of FIG. 2 that is applied to the receiving unit of FIG. 8.

FIG. 10 is a table illustrating the receiving operation of FIG. 9, which corresponds to the table of FIG. 5.

### DETAILED DESCRIPTION OF THE INVENTION

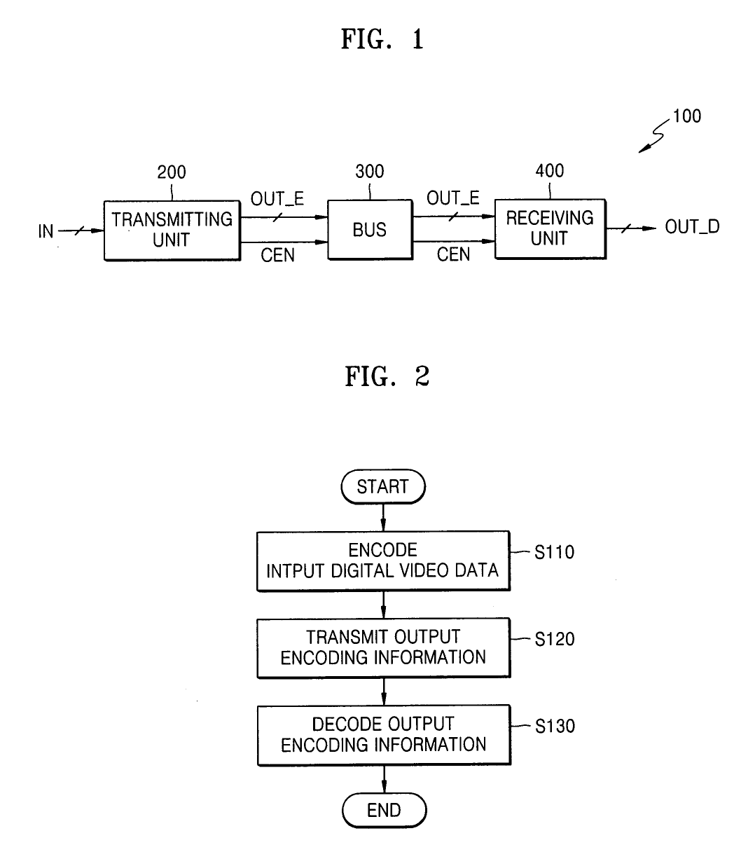

FIG. 1 is a block diagram illustrating a digital video data transmission system according to an embodiment of the present invention. Referring to FIG. 1, the digital video data transmission system 100 comprises a transmitting unit 200, a bus 300, and a receiving unit 400.

Digital video data IN are consecutively input in the transmitting unit 200 by an image processing unit (not shown) such as a video controller. Each of digital video data IN constitutes a single image (or frame) background. Differential values between adjacent digital video data IN are relatively small, which is referred to as spatial locality of video data.

The transmitting unit 200 transmits valid first data (first data) in input digital video data IN having spatial locality to the bus 300 as output encoding information OUT_E, CEN without bit-inversion coding the first data. The transmitting unit 200 bit-inversion codes previous data of output encoding data OUT_E corresponding to input digital video data IN based on differential values of adjacent digital video data IN, and transmits the bit-inversion coded value to the bus 300 as output encoding information OUT_E, CEN.

Output encoding information OUT_E, CEN includes output encoding data OUT_E and coding enable information CEN that indicates whether to bit-inversion encode and previous data of output encoding data OUT_E.

Output encoding data OUT_E includes polarity change information and bit-inversion coding information. Polarity change information indicates to invert the most significant bit included in previous data of output encoding data OUT_E when the polarity of differential values changes. Bit-inversion coding information includes information bit-inversion coded according to absolute values of differential values among adjacent digital video data IN.

The receiving unit 400 outputs output encoding information OUT_E, CEN in parallel received from the bus 300, i.e., the first data, as output decoding data OUT_D having the same value as that of the first data without decoding the first data, decodes output encoding information OUT_E, CEN received in parallel from the bus 300 based on differential values, and outputs output decoding data OUT_D having the same value as that of input digital video data IN. Output decoding data OUT_D may be transmitted to a display device (not shown) such as a liquid crystal display (LCD) panel.

FIG. 2 is a flow chart describing a digital video data transmission method according to an embodiment of the present invention. The digital video data transmission method of FIG. 2 can be applied to the digital video data transmission system of FIG. 1.

Referring to FIGS. 1 and 2, in transmitting operation S110, valid first data (first data) in input digital video data IN having spatial locality is not bit-inversion coded, and is transmitted to the bus 300 as output encoding information OUT_E, CEN. Previous data of output encoding data OUT_E corresponding to input digital video data IN is bit-inversion coded based on differential values among adjacent digital video data IN, and the bit-inversion coded value is transmitted to the bus 300 as output encoding information OUT_E, CEN.

Output encoding information OUT_E, CEN includes output encoding data OUT_E and coding enable information CEN that indicates whether to bit-inversion encode and previous data of output encoding data OUT_E.

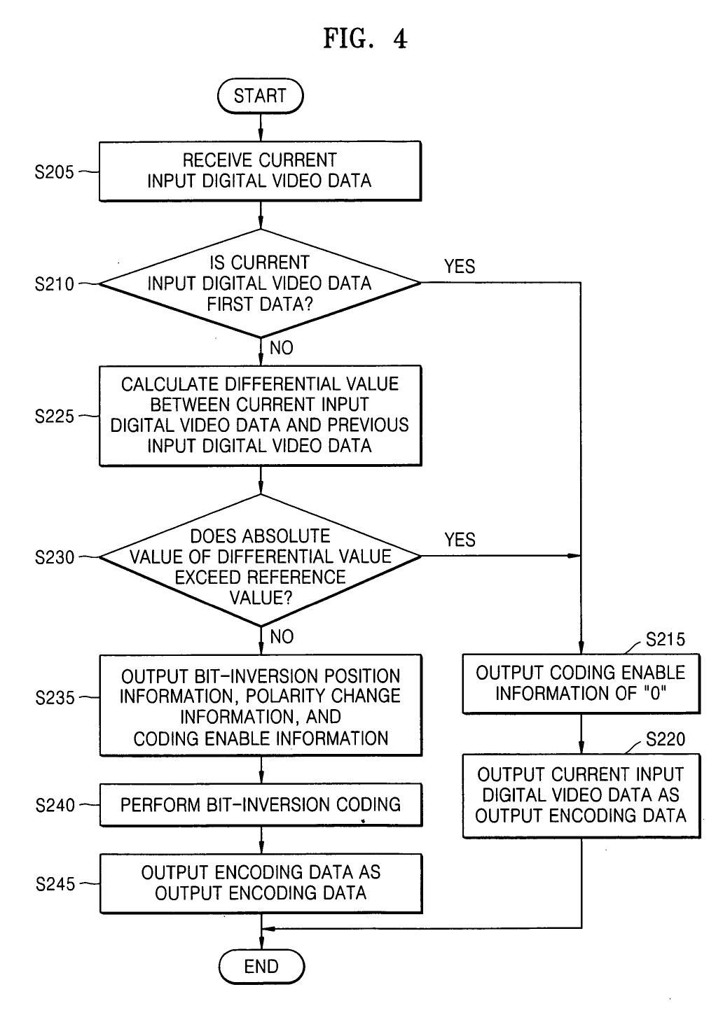

Output encoding data OUT_E includes polarity change information and bit-inversion coding information. Polarity change information indicates to invert the most significant bit included in previous data of output encoding data OUT_E when the polarity of differential values changes. Bit-inversion coding information includes information bit-inversion coded according to absolute values of differential values between adjacent digital video data IN. The transmitting operation S110 will be described in detail with reference to FIG. 4.

In transferring operation S120, output encoding information OUT_E, CEN is transferred in parallel through the bus 300.

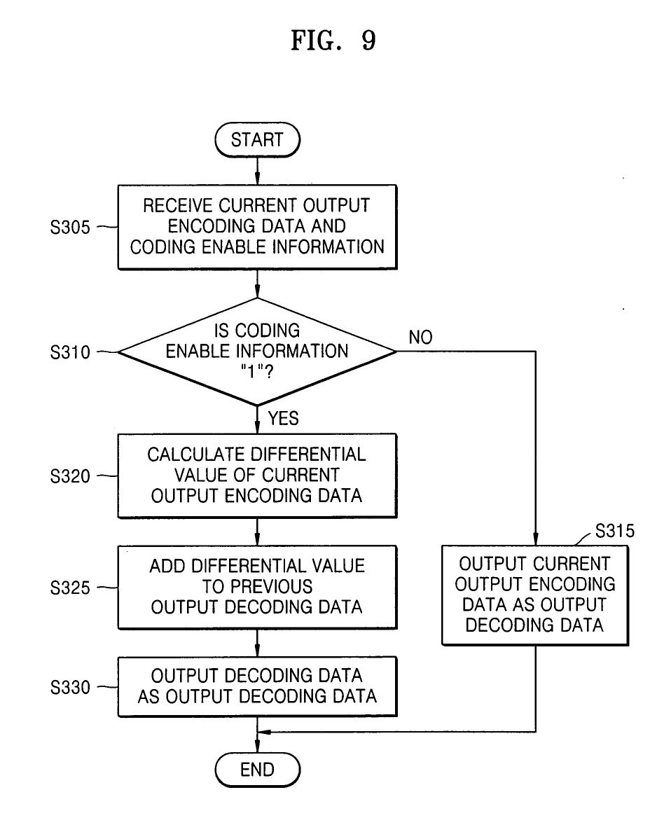

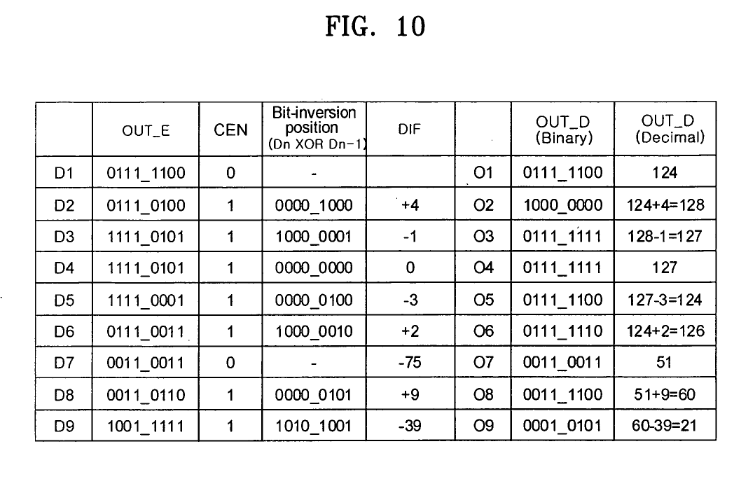

In receiving operation S130, output encoding information OUT_E, CEN transmitted through the bus 300, i.e., the first data, is received without being decoded, and output encoding information OUT_E, CEN transmitted through the bus 300 is decoded and received based on differential values. The receiving operation S130 will be described in detail with reference to FIG. 9.

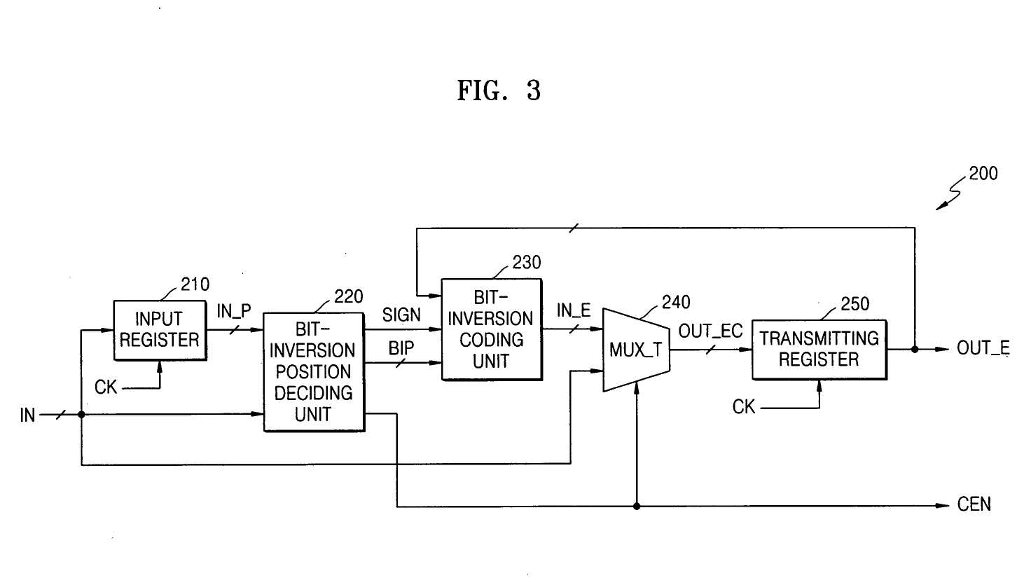

FIG. 3 is a block diagram of the transmitting unit of FIG. 1. Referring to FIG. 3, the transmitting unit 200 comprises an input register 210, a bit-inversion position deciding unit 220, a bit-inversion coding unit 230, a transmitting multiplexer MUX_T 240, and a transmitting register 250.

The input register 210 converts previous input digital video data IN_P stored in response to a predetermined cycle of a clock signal CK into current input digital video data IN, and stores the converted current input digital video data IN. Current input digital video data IN may be 8-bit data.

The bit-inversion position deciding unit 220 calculates a differential value between current input digital video data IN and previous data IN_P of current input digital video data IN, and outputs coding enable information CEN, polarity change information SIGN, and bit-inversion position information BIP based on the calculated differential value. Coding enable information CEN is transferred to a control terminal of the MUX_T 240 and the bus 300.

Coding enable information CEN has a 1-bit value. When an absolute value of the differential value is less than a predetermined reference value, coding enable information CEN is “1 (logic high)”. When current input,digital video data IN is valid first data or the absolute value of the differential value is more than the predetermined reference value, coding enable information CEN is “0 (logic low)”.

Coding enable information CEN of “1” indicates to bit-inversion code previous data of output encoding data OUT_E corresponding to current input digital video data IN. Coding enable information CEN of “0” indicates the bit-inversion coding unit 230 not to bit-inversion code current input digital video data IN but to bypass current input digital video data IN.

Polarity change information SIGN has a 1-bit value. Polarity change information SIGN indicates to invert the most significant bit (MSB) included in previous data of output encoding data OUT_E corresponding to current input digital video data IN when the polarity of the differential value changes. A default polarity of the differential value is established as plus (+).

Bit-inversion position information BIP has a plurality of bit values, and indicates a bit-inversion position of previous data of output encoding data OUT_E corresponding to current input digital video data IN according to the absolute value of the differential value.

The bit-inversion coding unit 230 bit-inversion codes previous data of output encoding data OUT_E corresponding to current input digital video data IN based on polarity change information SIGN and bit-inversion position information BIP and outputs encoding data IN_E. The bit-inversion coding unit 230 is called a relative difference bit-inversion (RDBI) coding unit.

The MUX_T 240 selects one of current input digital video data IN and encoding data IN_E in response to coding enable information CEN, and outputs the selected data as current output encoding data OUT_EC. When coding enable information CEN is “1”, the MUX_T 240 selects encoding data IN_E, when coding enable information CEN is “0”, the MUX_T 240 selects current input digital video data IN.

The transmitting register 250 converts output encoding data OUT_E into current output encoding data OUT_EC in response to a predetermined cycle of the clock signal CK, and stores current output encoding data OUT_EC. The stored current output encoding data OUT_EC is transferred to the bus 300 and bit-inversion coding unit 230.

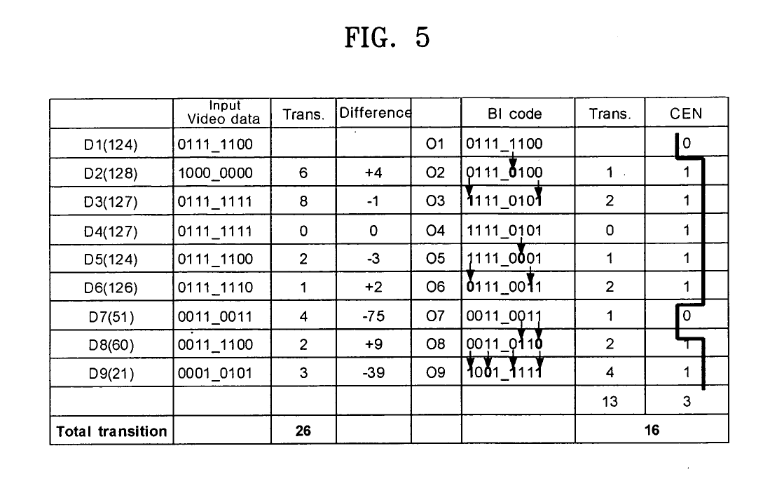

FIG. 4 is a flow chart describing the transmitting operation S110 that is applied to the transmitting unit of FIG. 3. FIG. 5 is an example of a table illustrating the transmitting operation of FIG. 4.

In receiving operation S205, the input register 210, bit-inversion position deciding unit 220, and the MUX_T 240 receive current input digital video data IN. Referring to FIG. 5, current input digital video data IN are consecutively received in the order of first data through ninth 8-bit data values D1˜D9. First data value D1 (124)=0111_{—}1100, and 124 in parenthesis is a decimal number corresponding to a binary number 0111_{—}1100.

In first confirming operation S210, the bit-inversion position deciding unit 220 determines whether the received current input digital video data IN is valid first data D1. If the received current input digital video data IN is determined to be first data D1, a first coding information outputting operation S215 is performed. When the received current input digital video data IN is not determined to be first data D1, i.e., the received current input digital video data IN is one of second data through ninth data D2˜D9, a calculating operation S225 is performed.

In first coding information outputting operation S215, the bit-inversion position deciding unit 220 outputs coding enable information CEN of “0”.

In first outputting operation S220, the MUX_T 240 outputs current input digital video data IN as output encoding data OUT_E in response to coding enable information CEN of “0”. Referring to FIG. 5, first data D1 is output as first encoding data 01, i.e., output encoding data OUT_E without being bit-inversion coded.

In calculating operation S225, the bit-inversion position deciding unit 220 calculates a differential value between current input digital video data IN and previous input data IN_P stored in the input register 210. Referring to FIG. 5, when current input digital video data IN is second data D2 128, and previous input data IN_P is first data D1 124, the differential value is +4. Differential values between input data D3˜D9 are calculated in the same manner as calculating the differential value +4.

Next, in a second confirming operation S230, the bit-inversion position deciding unit 220 determines whether absolute values of difference values calculated in operation S225 exceed a reference value. Since absolute values of differential values between adjacent data among 8-bit input digital video data IN having spatial locality are mostly less than 64, the reference value can be established as 63. When the reference value can be established as 63, Hamming distance of adjacent output encoding data OUT_E is below 3.

If the absolute values of differential values calculated in operation S225 exceed the reference value, the first coding information outputting operation S215 and the first outputting operation S220 are performed. Referring to FIG. 5, seventh data D7 51 is 0011_{—}0011, and sixth data D6 126 is 0111_{—}1110. Since an absolute value of the differential value between seventh data and sixth data is 75, which exceeds the reference value of 63, coding enable information CEN is “0” and is output as seventh encoding data 07 without being bit-inversion coded.

If absolute values of differential values calculated in operation S225 exceed the reference value, a second coding information outputting operation S235 is performed. In second coding information outputting operations S235, the bit-inversion position deciding unit 220 outputs bit-inversion position information BIP, polarity change information SIGN, and coding enable information CEN based on differential values.

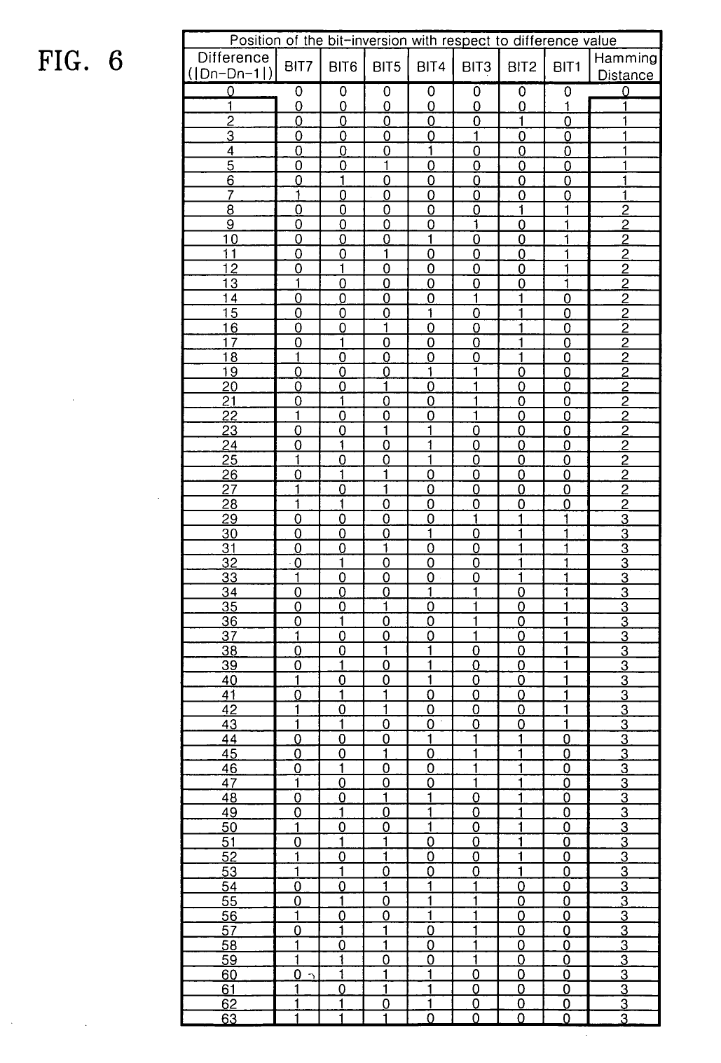

Bit-inversion position information BIP according to absolute values of differential values is output from a table of FIG. 6. FIG. 6 is an example of a table including bit-inversion position codes according to absolute values of differential values. Bit-inversion position codes included in the table of FIG. 6 may be changed. Referring to the table of FIG. 6, when an absolute value of the differential value is 0, bit-inversion position code has a Hamming distance of 0, when an absolute value of the differential value is more than 1 and less than 7, bit-inversion position codes have a Hamming distance of 1, when an absolute value of the differential value is more than 8 and less than 28, bit-inversion position codes have a Hamming distance of 2, and when an absolute value of the differential value is more than 29 and less than 63, bit-inversion position codes have a Hamming distance of 3. In bit-inversion position codes, “0” indicates a bit-inversion position code which is not bit-inversion coded, and “1” is a bit-inversion position code which is bit-inversion coded.

Referring to FIGS. 5 and 6, when current input digital video data IN is second data D2, bit-inversion position information BIP, polarity change information SIGN, and coding enable information CEN are output as indicated below. The absolute value of differential value regarding second data D2 is 4. Referring to the table of FIG. 6, a bit-inversion position code corresponding to the absolute value of differential value of 4 is 000_{—}1000. The bit-inversion position of first encoding data 01 corresponding to first data D1 is a fourth bit of first encoding data 01. Polarity change information SIGN regarding second data D2 does not indicate to invert an eighth bit, i.e., the most significant bit of first encoding data 01, since polarity of the differential value does not change. That is, the most significant bit of first encoding data 01, i.e., the eighth bit, remains uninverted. Coding enable information CEN is “1” indicating bit-inversion code since the input digital video data D2 is not first data D1 and an absolute value of the differential value is less than the reference value.

Coding information (BIP, SIGN, CEN) regarding input digital video data D3-D6, D8, and D9 is output in the same manner as outputting bit-inversion position information BIP, polarity change information SIGN, and coding enable information CEN regarding second data D2. Bit-inversion position information BIP regarding third data D3 indicates to invert the first bit of second encoding data 02. Polarity change information SIGN regarding third data D3 indicates to invert an eighth bit, i.e., the most significant bit of second encoding data 02 since the polarity of the differential value changes. Coding enable information CEN regarding third data D3 is “1” since the input digital video data D3 is not the first data D1, and an absolute value of the differential value is less than the reference value.

In bit-inversion coding operation S240, the bit-inversion coding unit 230 bit-inversion codes previous data of output encoding data OUT_E corresponding to current input digital video data IN based on bit-inversion position information BIP and polarity change information SIGN, and outputs encoding data IN_E.

Referring to FIG. 5, when current input digital video data IN is second data D2, generation of second encoding data 02, i.e., 01111_{—}0100, corresponding to second data D2, is described as indicated below. Since bit-inversion position information BIP regarding first encoding data 01 indicates to invert a fourth bit, the fourth bit of first encoding data 01 is inverted. The eighth bit, i.e., the most significant bit of first encoding data 01, remains uninverted based on polarity change information SIGN that indicates no change in polarity of the differential value. Bit-inversion code (BI code) of second encoding data 02, i.e., encoding data IN_E, is generated as 0111_{—}0100. Encoding data 03˜06, 08, and 09 are generated in the same manner as generating second encoding data 02.

In a second outputting operation S245, the MUX_T 240 outputs data encoded in the bit-inversion coding operation S240 as output encoding data OUT_E in response to coding enable information of “1”.

When the transmitting unit 200 of FIG. 3 transmits nine input digital video data D1˜D9 according to the transmitting operations of FIG. 4, the number of bit transitions is shown in FIG. 5. Referring to FIG. 5, the number of bit transitions according to the present invention is 16, and the number of bit transitions according to the conventional art is 26. The number of bit transitions is reduced by about 38%.

Therefore, the digital video data transmission system and digital video data transmission method bit-inversion code digital video data having spatial data locality so as to make a Hamming distance short according to differential values of adjacent data and transmit the bit-inversion coded digital video data to the bus. As a result, as the number of transitions of bits included in the digital video data transmitted through the bus decreases, power consumption and electromagnetic interference decrease.

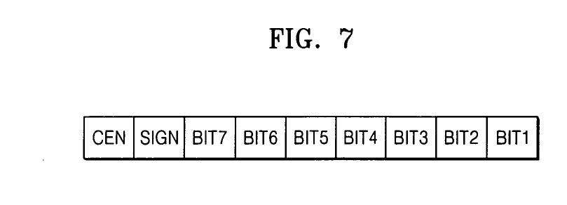

FIG. 7 is an example of output encoding information generated by the transmitting unit 300 of FIG. 3 according to the transmitting operations of FIG. 4. FIG. 7 illustrates a bit constitution of output encoding information OUT_E, CEN when input digital video data IN is 8-bit data.

Referring to FIG. 7, a ninth bit of output encoding information OUT_E, CEN is coding enable information CEN, an eighth bit of output encoding data OUT_E is a bit including polarity change information SIGN, and first through seventh bits (BIT1-BIT7) of output encoding data OUT_E are bit-inversion coding information according to absolute values of differential values of adjacent data.

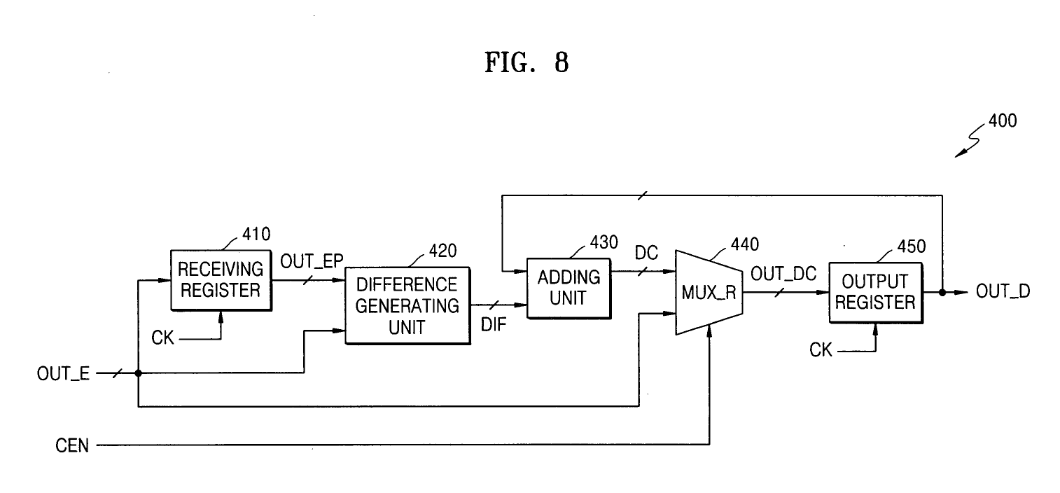

FIG. 8 is a block diagram of the receiving unit 400 of FIG. 1. Referring to FIG. 8, the receiving unit 400 comprises a receiving register 410, a differential generating unit 420, an adding unit 430, a receiving multiplexer MUX_R 440, and an output register 450.

The receiving register 410 receives current output encoding data OUT_E transmitted through the bus 300 in response to a predetermined cycle of the clock signal CK to convert previous output encoding data OUT_EP into current output encoding data OUT_E, and store current output encoding data OUT_E.

The differential generating unit 420 detects a bit-inversion position by performing an exclusive OR (XOR) operation on current output encoding data OUT_E and previous output encoding data OUT_EP stored in the receiving register 410. The differential generating unit 420 generates an absolute value of the differential value DIF corresponding to the detected bit-inversion position with reference to the table of FIG. 6. The differential generating unit 420 decides the polarity of the differential value DIF based on a change in the most significant bit of current output encoding data OUT_E in comparison with the most significant bit of previous output encoding data OUT_EP. To be more specific, when the most significant bit of current output encoding data OUT_E is different from the most significant bit of previous output encoding data OUT_EP, i.e., from “0” to “1” or from “1” to “0”, the polarity of the differential value DIF changes, and the default polarity for the polarity of the differential value is established as plus +.

The adding unit 430 outputs decoding data DC by adding the differential value DIF to previous output decoding data OUT_D. When output encoding data OUT_E is 8-bit data, the adding unit 430 is realized as an 8-bit adder.

The MUX_R 440 selects one of decoding data DC and current output encoding data OUT_E in response to coding enable information CEN transmitted through the bus 300 and outputs the selected data as current output decoding data. When coding enable information CEN is “1”, the MUX_R 440 selects decoding data DC, and when coding enable information CEN is “0”, the MUX_R 440 selects current output encoding data OUT_E.

The output register 450 converts previous output decoding data OUT_D into current output decoding data OUT_DC in response to a predetermined cycle of the clock signal CK, and stores current output decoding data OUT_DC.

FIG. 9 is a flow chart describing the receiving operation S130 of FIG. 2 that is applied to the receiving unit 400 of FIG. 8. FIG. 10 is an example table illustrating the receiving operation of FIG. 9, which corresponds to the table of FIG. 5. The receiving operation S130 of FIG. 9 will now be described with reference to FIGS. 8 and 10.

In receiving operation S305, the receiving register 410, the differential generating unit 420, and the MUX_R 440 receive current output encoding data OUT_E. The MUX_R 440 receives coding enable information CEN. Referring to FIG. 10, current output encoding data OUT_E and coding enable information CEN corresponding to current output encoding data OUT_E are received in the order of first data through ninth 8-bit data values (D1-D9).

In confirming operation S310, the MUX_R 440 confirms whether coding enable information CEN is “1”. When coding enable information CEN is not confirmed as “1”, i.e., when coding enable information CEN is confirmed as “0”, a first outputting operation S315 is performed. When coding enable information CEN is confirmed as “1”, a generating operation S320 is performed.

In first outputting operation S315, the MUX_R 440 outputs current output encoding data OUT_E as output decoding data OUT_D in response to coding enable information CEN of “0”. Referring to FIG. 10, first data D1 is valid first data of output encoding data OUT_E, and seventh data D7 is not decoded, i.e., bypassed, and is output as output decoding data OUT_D since the absolute value of the differential value (−75) regarding seventh data D7 exceeds the reference value 63.

In generating operation S320, the differential generating unit 420 detects a bit-inversion position by performing the exclusive OR (XOR) operation of current output encoding data OUT_E and previous output encoding data OUT_EP stored in the receiving register 410, and generates (or calculates) the absolute value of the differential value DIF corresponding to the detected bit-inversion position with reference to the table of FIG. 6. The differential generating unit 420 decides the polarity of the differential value DIF based on the change in the most significant bit of current output encoding data OUT_E in comparison with the most significant bit of previous output encoding data OUT_EP.

Supposing that current output encoding data OUT_E is second data D2 in the table of FIG. 10, the differential value DIF regarding second data D2 is generated as indicated below. An XOR value D2 XOR D1 of second data D2 and first data D1 is 0000_{—}1000, and an absolute value of the differential value DIF corresponding to 0000_{—}1000 is 4 in the table of FIG. 6. Since the most significant bit (0) of the second data D2 and the most significant bit (0) of the first data remain uninverted, the polarity of the differential value DIF becomes a plus default value and the final differential value is +4. Differential values of data D3˜D6, D8, and D9 are generated in the same manner as generating the differential value regarding second data D2.

In adding operation S325, the adding unit 430 outputs decoding data DC by adding the differential value DIF generated in the generating operation S320 to previous output decoding data OUT_D.

In second outputting operation S330, the MUX_R 440 outputs decoding data DC as output decoding data OUT_D in response to coding enable information CEN of “1”.

Supposing that current output encoding data OUT_E is second data D2 in the table of FIG. 10, the second output value 02 of output decoding data OUT_D regarding second data D2 is calculated below. The differential value +4 is added to 124 (0111_{—}1100) which is a value of first output decoding data 01 so that a value of second output decoding data 02 is decoded as 128 (1000_{—}0000). Differential values of decoding data O3˜O6, O8, and O9 are calculated in the same manner as calculating second output decoding data 02.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the present invention is defined not by the detailed description of the invention but by the appended claims, and all differences within the scope of the present invention will be construed as being included in the present invention.

What is claimed is:

1. A digital video data transmission system, comprising:
a transmitting unit transmitting valid first data in input digital video data having spatial locality to a bus as output encoding information without bit-inversion coding the first data, bit-inversion coding previous data of output encoding data corresponding to the input digital video data based on differential values of adjacent digital video data, and transmitting the bit-inversion coded value to the bus as the output encoding information; and
a receiving unit not decoding output encoding information transmitted in parallel through the bus in the first data, but decoding output encoding information transmitted in parallel through the bus based on the differential values,
wherein the output encoding information includes the output encoding data and coding enable information that indicates whether to bit-inversion encode previous data of the output encoding data.

2. The system of claim 1, wherein the output encoding information comprises:
polarity change information indicating to invert the most significant bit included in previous data of the output encoding data when the polarity of the differential values changes; and
bit-inversion coding information including information bit-inversion coded according to absolute values of the differential values.

3. The system of claim 2, wherein a default polarity of the differential values is established as positive (+).

4. The system of claim 3, wherein:
the transmitting unit transmits input digital video data to the bus as output encoding information without bit-inversion coding previous data of the output encoding data corresponding to the input digital video data when an absolute value of a differential value regarding the input digital video data exceeds a predetermined reference value; and
the receiving unit does not decode the output encoding data that is not bit-inversion coded and is transmitted through the bus.

5. The system of claim 4, wherein the transmitting unit comprises:
a bit-inversion position deciding unit calculating a differential value between the input digital video data and previous data of the input digital video data, and outputting bit-inversion position information that indicates a bit-inversion position of previous data of output encoding data according to the absolute value of the differential value, the coding enable information, and the polarity change information;
a bit-inversion coding unit bit-inversion coding previous data of the output encoding data corresponding to the input digital video data based on the polarity change information and the bit-inversion position information, and outputting the coded value as encoding data; and
a transmitting multiplexer selecting one of the input digital video data and the encoding data in response to the coding enable information, and outputting the selected data as the output encoding data.

6. The system of claim 5, wherein the bit-inversion position information is output from a table including bit-inversion position codes according to absolute values of the differential values.

7. The system of claim 6, wherein the Hamming distance of bit-inversion position codes included in the table is below 3, when the reference value is established as 63.

8. The system of claim 5, wherein the transmitting unit further comprises an input register storing previous data of the input digital video data.

9. The system of claim 5, wherein the transmitting unit further comprises a transmitting register storing the output encoding data.

10. The system of claim 6, wherein the receiving unit comprises:
a differential generating unit detecting the bit-inversion position by performing an exclusive OR (XOR) operation on the output encoding data and previous data of the output encoding data, generating an absolute value of the differential value corresponding to the detected bit-inversion position with reference to the table, and deciding the polarity of the differential value based on a change in the most significant bit of the output encoding data in comparison with the most significant bit included in previous data of the output encoding data;
an adding unit outputting decoding data by adding the differential value to previous data of the output decoding data corresponding to the output encoding data; and
a receiving multiplexer selecting one of the decoding data and the output encoding data in response to the coding enable information, and outputting the selected data as the output decoding data.

11. The system of claim 10, wherein the receiving unit further comprises a receiving register storing previous data of the output encoding data.

12. The system of claim 10, wherein the receiving unit further comprises an output register storing the output decoding data.

13. A digital video data transmission method, comprising:
transmitting valid first data in input digital video data having spatial locality-to a bus as output encoding information without bit-inversion coding the first data, bit-inversion coding previous data of output encoding data corresponding to the input digital video data based on differential values of adjacent digital video data, and transmitting the bit-inversion coded value to the bus as the output encoding information;
transferring in parallel the output encoding information transmitted through the bus; and
receiving the output encoding information transmitted through the bus by not decoding the first data, and receiving the output encoding information transmitted through the bus by decoding the output encoding information based on the differential values,
wherein the output encoding information includes the output encoding data and coding enable information that indicates whether to bit-inversion encode previous data of the output encoding data.

14. The method of claim 13, wherein the output encoding information comprises:
polarity change information indicating to invert the most significant bit included in previous data of the output encoding data when the polarity of the differential values changes; and
bit-inversion coding information including information bit-inversion coded according to absolute values of the differential values.

15. The method of claim 14, wherein a default polarity of polarity of the differential values is established as positive (+).

16. The method of claim 15, wherein the transmitting further comprises:
transmitting input digital video data to the bus as output encoding information without bit-inversion coding previous data of the output encoding data corresponding to the input digital video data when an absolute value of a differential value regarding the input digital video data exceeds a predetermined reference value; and
receiving the output encoding data that is not bit-inversion coded and is transmitted through the bus by not decoding the output encoding data.

17. The method of claim 16, wherein the transmitting comprises:
calculating a differential value between the input digital video data and previous data of the input digital video data, and outputting bit-inversion position information that indicates a bit-inversion position of previous data of output encoding data according to the absolute value of the differential value, the coding enable information, and the polarity change information;
bit-inversion coding previous data of the output encoding data corresponding to the input digital video data based on the polarity change information and the bit-inversion position information, and outputting the coded value as encoding data; and
selecting one of the input digital video data and the encoding data in response to the coding enable information, and outputting the selected data as the output encoding data.

18. The method of claim 17, wherein the bit-inversion position information is output from a table including bit-inversion position codes according to absolute values of the differential values.

19. The method of claim 18, wherein the Hamming distance of bit-inversion position codes included in the table is below 3, when the reference value is established as 63.

20. The method of claim 17, wherein the transmitting further comprises storing previous data of the input digital video data.

21. The method of claim 17, wherein the transmitting further comprises storing the output encoding data.

22. The method of claim 18, wherein the receiving comprises:
detecting the bit-inversion position by performing an exclusive OR (XOR) operation on the output encoding data and previous data of the output encoding data, generating an absolute value of the differential value corresponding to the detected bit-inversion position with reference to the table, and deciding the polarity of the differential value based on a change in the most significant bit of the output encoding data in comparison with the most significant bit included in previous data of the output encoding data;
outputting decoding data by adding the differential value to previous data of the output decoding data corresponding to the output encoding data; and
selecting one of the decoding data and the output encoding data in response to the coding enable information, and outputting the selected data as the output decoding data.

23. The method of claim 22, wherein the receiving further comprises storing previous data of the output encoding data.

24. The method of claim 22, wherein the receiving further comprises storing the output decoding data.
